(19) United States
(12) Patent Application Publication
(10) Pub. No.: US 2017/0110645 A1
(43) Pub. Date: Apr. 20, 2017

(54) THERMOELECTRIC MATERIAL WITH AN ANTIFLUORITE STRUCTURE TYPE MATRIX AND METHOD OF MANUFACTURING THE MATERIAL

(71) Applicant: COMMISSARIAT À L'ENERGIE ATOMIQUE ET AUX ENERGIES ALTERNATIVES, Paris (FR)

(72) Inventors: Natalio MINGO BISQUERT, Sassenage (FR); Guillaume BERNARD-GRANGER, Mazan (FR); Radivoje VRACAR, Belgrade (RS); Nebil AYAPE KATCHO, Vitoria-Gasteiz (ES)

(21) Appl. No.: 14/883,343

(22) Filed: Oct. 14, 2015

(51) Int. Cl. H01L 35/20; B22F 3/105; B22F 3/24; C22C 13/00

(52) U.S. Cl. CPC H01L 35/20; C22C 13/00; B22F 3/105; B22F 3/24; B22F 2003/1051; B22F 2202/13; B22F 2301/30

(57) ABSTRACT

A method of manufacturing a thermoelectric material including: providing a half-Heusler compound of MgCuSn nanoparticles, obtaining a powder by mechanical alloying by using Mg chips, Si fine powder, Sn fine powder and Sb powder, the half-Heusler compound of MgCuSn nanoparticles and cyclohexane solution,wherein the weight percent V, of the cyclohexane solution is comprised between 0.5 wt % and 4.0 wt % and wherein the volume percent V_{HH} of the Half-Heusler compound of MgCuSn nanoparticles satisfies: 1.4 vol %<V_{HH}<2.0 vol %.

### FIELD OF THE INVENTION

The present invention relates to a thermoelectric material and a method of manufacturing such a material, particularly to a thermoelectric material comprising a matrix of the antifluorite type structure with embedded inclusions.

### DESCRIPTION OF THE RELATED ART

The non-optimized use of fossil fuels is becoming more expensive and it is a major contributor to environmental pollution. Thus, global awareness on environmental issues, and rising fossil fuel prices have favored the development of energy conversion techniques in recent years, including direct thermoelectric energy conversion.

Thermoelectric energy (TE) conversion is advantageous over other energy conversion techniques, because it does not pollute the atmosphere. In addition, a TE conversion device is completely solid state. Therefore, the device is robust, long lasting, and easy to manufacture. Furthermore, this type of device could be used for applications in remote and/or harsh environments, and even for applications in space or aeronautics, thanks to its lightweight and its vibration-free nature.

Thermoelectric materials constitute the essential elements in direct TE conversion devices. Thermoelectric materials have the ability to directly convert temperature gradients to electric energy and vice-versa. By proper doping, N-type and P-type thermoelectric materials are achievable. Thermoelectric materials are typically used by joining together P-type and N-type thermoelectric materials. Such a joint pair forms a thermocouple, i.e. a thermoelectric device.

The performance of a thermoelectric device depends on the physical and structural characteristics of the thermoelectric materials forming the device. To evaluate the efficiency and the aptitude of a thermoelectric material to convert thermal energies and electric energies into one another, a dimensionless figure of merit ZT (Z=S² σ/κ where S is the Seebeck coefficient, a the electrical conductivity, κ the thermal conductivity, and T is the absolute temperature) is generally used. The higher the ZT value, the better the thermoelectric behavior for a given material. Generally, a material is considered as a good thermoelectric material if its ZT exceeds 1 at some temperature.

The best known thermoelectric materials contain rare elements and are difficult to manufacture. This strongly limits the interest of the TE conversion devices. Thus there is a need to easily manufacture a thermoelectric material with high ZT and based on ordinary materials.

To improve the quality of a material, from a thermoelectric point of view, the addition of nanophases can be used as a solution to increase the ZT value of a solid material. Nanophases addition to a solid matrix lattice could be a reliable and efficient solution, on condition that the nanophases do not perturb the matrix lattice by creating dislocations, or by introducing residual stresses. These dislocations or stresses can negatively affect electron mobility, and thus the ZT value of the material.

Therefore, it is a real challenge to find a right nanophase which is compatible with the crystal structure and lattice parameter of the embedding matrix.

### SUMMARY OF THE INVENTION

There is a need to provide a thermoelectric material easy to manufacture and having a high ZT value. This need tends to be satisfied by providing a thermoelectric compound comprising :
a first thermoelectric material having an antifluorite matrix,
a second material of the Half-Heusler structure phase forming embedded inclusions in the antifluorite matrix made of the first thermoelectric material.

Preferably, the antifluorite matrix having a composition expressed by a formula:

Mg₂SiₓSN₁₋ₓ

where, x is a value satisfying 0.35<x<0.4,

and wherein the embedded inclusions are MgCuSn nanoparticles.

According to one embodiment, the antifluorite matrix having a composition expressed by a formula:

Mg₂SiₓA_{y}Sn_{1-x-y}

where, A is Sb or Bi, x is a value satisfying 0.35<x<0.4, and y is a value satisfying 0.005<y<0.03,

and wherein the embedded inclusions are MgCuSn nanoparticles. Advantageously, the thermoelectric material has a dimensionless figure of merit ZT higher than 1.2-1.3 at 510° C.

Preferably, the thermoelectric compound comprises a volume percent V_{HH} of the Half-Heusler compound of MgCuSn nanoparticles satisfying:

1.4% vol.<=V_{HH}<=2.0% vol.

According to another embodiment, we provide a thermoelectric conversion module, comprising:
a first element made from a first n-type thermoelectric material,
a second element made from a second p-type thermoelectric material,
an electric connecting element in electric contact with the first element and the second element so as to form a thermocouple,
   wherein the first n-type thermoelectric material is based of the thermoelectric compound described above.

We tend to satisfy the above need by providing also a method of manufacturing a thermoelectric compound comprising:
providing a Half-Heusler compound of MgCuSn nanoparticles,
obtaining a powder by mechanical alloying, Mg chips, Si powder, Sn powder and Sb powder, with the Half-Heusler compound of MgCuSn nanoparticles and with a process control agent solution,
   wherein the weight percent V_{c} of the process control agent solution is comprised between 0.5 wt % and 4.0 wt % and wherein the volume percent V_{HH} of the Half-Heusler compound of MgCuSn nanoparticles is comprised between 1.4 vol % and 2.0 vol % inclusive.

According to one embodiment, the process control agent solution is a cyclohexane solution.

Preferably, the mechanical alloying is performed in a high planetary mill comprising a sealed zirconia jar provided with at least two zirconia balls, and wherein the ratio of the mass of the balls to the mass of the powder is kept between 15 and 30 and preferably kept at about 26.

Advantageously, wherein the Mg chips, the Si powder, the Sn powder, the Sb powder, the Half-Heusler compound of MgCuSn nanoparticles and the process control agent solution are placed into the zirconia jar inside a glove box in an inert atmosphere.

According to one embodiment, the sealed zirconia jar is milled for a total time arranged between 10 and 100 hours at a speed arranged between 200 and 400 rpm. Preferably, milling is performed with a rotation sequence of 10 minutes in a first direction, followed by a pause of 2 minutes and another rotation sequence in a second direction opposite to the first direction.

According to an embodiment, the obtained powder is sintered so as to obtain a dense sample of the thermoelectric material. Advantageously, the obtained powder is kept in an inert atmosphere before the sintering step. Preferably, the sintering process is performed by spark plasma sintering and comprises at least one pressure step performed at a pressure arranged between 5 and 100 MPa, and at a sintering temperature T_{S} arranged between 500 and 720° C. inclusive.

More preferably, the sintering process is performed in a spark plasma sintering machine and wherein the sintering process comprises a specific cooling step performed and controlled by the spark plasma sintering machine after the pressure step so as to decrease the temperature of the sintered material within the spark plasma sintering machine from the sintering temperature Ts to a cooling temperature Tc arranged between 150 and 400° C. Advantageously, the cooling step is performed with a cooling rate arranged between 10° C./min and 600° C./min until reaching the cooling temperature Tc.

### BRIEF DESCRIPTION OF THE DRAWINGS

Other advantages and features will become more clearly apparent from the following description of particular embodiments of the invention given for non-restrictive example purposes only and represented in the appended drawings in which:

FIGS. 1 and 2 illustrate XRD diagrams respectively after mechanical alloying and sintering, for two thermoelectric materials, one of which is manufactured according to an embodiment of the present invention,

FIG. 3 illustrates the temperature variations of the measured electrical conductivity for two thermoelectric materials, one of which is manufactured according to an embodiment of the present invention,

FIG. 4 illustrates the temperature variations of the measured Seebeck coefficient for two thermoelectric materials manufactured according to an embodiment of the present invention,

FIG. 5 illustrates the temperature variations of the measured thermal conductivity for two thermoelectric materials manufactured according to an embodiment of the present invention, and

FIG. 6 illustrates the temperature variations of the calculated ZT value for two thermoelectric materials manufactured according to an embodiment of the present invention.

### DETAILED DESCRIPTION OF THE INVENTION

A thermoelectric compound according to an embodiment of the present invention comprises a structure embedding matrix provided with embedded inclusions. Advantageously, the thermoelectric compound comprises a first thermoelectric material forming the structure embedding matrix, and having an antifluorite structure matrix, i.e. a structure matrix having a Fm3m space group (space group n^{o} 225).

Preferably, the structure embedding matrix comprises magnesium according to the formula Mg₂SiₓSn₁₋ₓ or according to the formula Mg₂SiₓA_{y}Sn_{1-x-y} with A designates possible other dopant species. The term “dopant” refers here to a chemical element introduced into the crystal lattice, in substitution, to create charge carriers: electrons for N-type doping, and holes for P-type doping.

These compounds have been extensively studied from a thermoelectric point of view, because of their interesting features particularly their large Seebeck coefficient, low electrical resistivity, and low thermal conductivity.

For example, a Mg₂SiₓSn₁₋ₓ based thermoelectric material is a promising material, because its ZT can reach a value close to 1 at certain temperatures. However, in the case where an interesting TE conversion device should be manufactured based on these materials, a higher ZT value is advantageous.

According to the above embodiment of the present invention, the thermoelectric compound comprises a second material of the Half-Heusler structure phase forming embedded inclusions in the antifluorite matrix made of the first thermoelectric material. The Half-Heusler inclusions have a predetermined composition. The Half-Heusler compound has crystal structure with a F43m space group (space group n^{o}216, C1_{b}). This family of compounds has a general formula XYZ with a 01:01:01 stoichiometry-type, and crystallizes in a noncentrosymmetric cubic structure. This type of structure can be characterized by the interpenetration of three sub-structures having face-centered cubic crystal structure (fcc), each of which is occupied by the atoms X, Y and Z. In principle, three non-equivalent atomic arrangements are possible in this type of structure, according to the occupations of the two equivalent and one non-equivalent positions by the atoms X, Y and Z.

The Half-Heusler compounds crystal symmetry is advantageously compatible with the crystal structure of an antifluorite embedding matrix. Furthermore, in accordance to the composition of the antifluorite structure, a Half-Heusler compound having lattice parameter close to that of the antifluorite structure matrix, can be found.

The advantageous features of the Half-Heusler compounds, particularly their compatibility with an antifluorite structure, allows an improved thermoelectric material comprising an antifluorite structure with Half-Heusler embedded inclusions to be realized. Advantageously, the ZT value of this type of thermoelectric material according to the present invention can reach a peak value around 1.3-1.4 at 510° C.

By including Half-Heusler inclusions allowing a close lattice matching with the antifluorite embedding structure, the ZT parameter can be greatly enhanced.

The major contribution of the Half-Heusler inclusions is to advantageously decrease the lattice-part of the thermal conductivity below that of the simple antifluorite structure matrix by efficiently scattering phonons.

According to another embodiment of the present invention, the antifluorite matrix has a composition expressed by the following composition formula:

Mg₂SiₓSn₁₋ₓ

where, x is a value satisfying 0.35<x<0.4.

Indeed a Mg₂SiₓSn₁₋ₓ based thermoelectric material without inclusions is considered as a promising thermoelectric material. Moreover, its constituent elements are nontoxic, environmentally friendly, and abundant. Thus Mg₂SiₓSn₁₋ₓ has long been recognized as a good candidate for thermoelectric applications. In addition, its features can be readily optimized by doping or alloying.

More preferably, the antifluorite matrix has a composition expressed by the following composition formula:

Mg₂SiₓA_{y}Sn_{1-x-y}

where, A is Sb or Bi, x is a value satisfying 0.35<x<0.4, and y is a value satisfying 0.005<y<0.03. Indeed, the adjunction of Tin or Bismuth atoms, with an appropriate quantity, can increase the Seebeck coefficient and/or the electric conductivity without detrimental distortion of the crystal structure.

According to another embodiment, the thermoelectric material is advantageously characterized by a dimensionless figure of merit ZT higher than 1.2-1.3 at 510° C.

Furthermore, for both these two last embodiments the embedded inclusions are a Half-Heusler compound, and preferably a Half-Heusler compound of MgCuSn nanoparticles. According to the present invention, the positive influence of a small volume percent, preferably between 1.4 vol % and 2.0 vol %, of Half-Heusler nanoparticles on the thermoelectric properties of a magnesium-silicon-tin antifluorite structure material is demonstrated.

Indeed, according to an embodiment, a first alloyed powder of Mg₂Si_{0.3875}Sn_{0.6}Sb_{0.0125} has been synthesized by mechanical alloying. A second powder has been synthesized by adding a volume percent V_{HH}=1.7 vol % of MgCuSn Half-Heusler nanoparticles during mechanical alloying of a Mg₂Si_{0.3875}Sn_{0.6}Sn_{0.0125} formulation and by using the same synthesis process of the first alloyed powder.

The first alloyed powder and the second alloyed powder have been densified using Spark Plasma Sintering (SPS) to create 20 mm diameter first and second compact samples, respectively. The mechanical alloying process and sintering process of first and second powders will be described below.

The electrical conductivity, the thermal conductivity and the ZT parameter were measured for the first and second compact samples. High electrical conductivity, low thermal conductivity and thus a very high ZT value approaching 1.4 at 510° C. were measured for the thermoelectric material comprising Half-Heusler nanoparticles.

The addition of Half-Heusler nanoparticles advantageously allows a great increase of the electrical conductivity, and decrease of thermal conductivity, especially lattice thermal conductivity, when compared to those for the material without the Half-Heusler inclusions. Therefore, the ZT value for the second compact sample is almost 60% higher than the ZT value measured for the first compact sample (thermoelectric material without Half-Heusler nanoparticles).

The thermoelectric material comprising an antifluorite matrix with Half-Heusler inclusions is a very efficient material, from a thermoelectric point of view, thanks to its high value of ZT parameter. Moreover, it is a thermoelectric material easy to manufacture, by using only two simple steps: mechanical alloying and spark plasma sintering.

According to a prefered embodiment, the antifluorite matrix of the thermoelectric material has a composition expressed by the following formula:

Mg₂SiₓA_{y}Sn_{1-x-y}

where, A is Sb or Bi, x is a value satisfying 0.35<x<0.4, and y is a value satisfying 0.005<y<0.03. Furthermore, the thermoelectric material comprises a Half-Heusler compound of MgCuSn nanoparticles, with a volume percent V_{HH} of the Half-Heusler compound of MgCuSn nanoparticles in the antifluorite matrix satisfying: 1.4% vol.≦V_{HH}≦2.0% vol. According to an embodiment of the present invention, a thermoelectric conversion module is provided. This module comprises a first element made from a first N-type thermoelectric material, and a second element made from a second P-type thermoelectric material. Furthermore, the module comprises an electric connecting element in electric contact with the first element and the second element so as to form a thermocouple. Advantageously, the first N-type thermoelectric material is based of the thermoelectric compound according to one of the previous embodiment disclosed above.

A method of manufacturing a thermoelectric material according to an embodiment of the present invention is a method of manufacturing a material containing a Half-Heusler MgCuSn nanoparticles embedded in an antiflorite matrix comprising magnesium, silicon, tin, and antimony.

First, a Half-Heusler compound of MgCuSn nanoparticles is provided. The space group of the Half-Heusler MgCuSn compound is F43m, and its lattice parameter is 6.48 Å. The Half-Heusler MgCuSn nanoparticles have a density of 5.042 g/cm³ and soft aggregates are made of elemental crystallites having an averaged diameter of 25 nm. This type of compound is referenced by the file n^{o} 103054 in the Inorganic Crystal Structure Database (ICDS).

Besides, a first powder is obtained by mechanical alloying and advantageously by mixing Mg chips, Si powder, Sn powder, and Sb powder. A second powder is obtained by adding furthermore the Half-Heusler MgCuSn nanoparticles.

Preferably, Mg chips are 99.99% pure, the Si powder is a 325 mesh and 99.999% pure powder, the Sn powder is a 325 mesh and 99.80% pure powder, and the Sb powder is a 325 mesh and 99.5% pure powder.

Preferably, the mechanical alloying is performed in a high energy planetary mill comprising a sealed zirconia jar provided with at least two zirconia balls. The ratio of the mass of the balls to the mass of the powder to be mixed is preferably kept between 15 and 30, and more preferably kept at about 26.

To reduce detrimental phenomenon during the process of mechanical alloying and to improve the yield of the obtained alloyed powder quantity, the method of manufacturing the thermoelectric material comprises advantageously the adjunction of a Process Control Agent (PCA) before the mechanical alloying to the different elements (Mg, Si, Sn, Sb, and Half-Heusler CuMgSn nanoparticles). The added PCA may be methanol, benzene, oxalic acid, stearic acid, or certain metallic stearates. Preferably, the added PCA is cyclohexane.

During the mechanical alloying, powder particles could get cold-welded to each other due to important plastic deformation. The adjunction of a PCA, especially cyclohexane, provides advantageously a balance between cold welding and fracturing of particles during milling. Moreover, the PCA increases the yield (the ratio between the recovered powder after mechanical alloying to the mass of the different elements placed) of the mechanical alloying process. Indeed, the PCA advantageously adsorbs on the surface of the powder particles and minimizes cold welding between powder particles and inhibits agglomeration.

Besides, it is possible to increase the weight percent V_{c} of the PCA that can be added to increase the yield of the alloying process. However, adding an important weight percent of PCA increases the particles size of the obtained alloying powder and can lead to organic residues in the final material, which is detrimental to the thermoelectric properties of the obtained material.

Thus, the weight percent V_{c} of the added cyclohexane solution is advantageously comprised between 0.5 wt % and 4.0 wt %. For the same reasons, i.e. to obtain an improved material with better thermoelectric properties, the volume percent V_{HH} of the Half-Heusler compound of MgCuSn nanoparticles satisfies: 1.4 vol≦V_{HH}≦2.0 vol %.

Before milling, all of the materials, PCA, precursors, and the Half-Heusler nanoparticles were placed in the zirconium jar at the same time. According to another particular embodiment, and to avoid contamination and combustion of magnesium, the PCA and precursors were loaded into the zirconia jar in an inert atmosphere, for example in an argon atmosphere. Then, the jar was sealed before milling.

According to a particular embodiment, the sealed zirconia jar is milled for a total time arranged between 10 and 100 hours at a speed arranged between 200 and 400 rpm. Preferably, the milling during the mechanical alloying is performed with a rotation sequence of 10 minutes in a first direction, followed by a pause of 2 minutes and another rotation sequence in a second direction opposite to the first direction.

The conditions of the mechanical alloying and the different mass of the elements were chosen so as to obtain a first alloyed powder having the following composition Mg₂Si_{0.3875}Sn_{0.6}Sb_{0.0125} and a second alloyed powder comprising the Half-Heusler nanoparticles, having the following composition Mg₂Si_{0.3875}Sn_{0.6}Sb_{0.0125}:MgCuSn.

After mechanical alloying, the first obtained powder and the second obtained powder, i.e. respectively without and with the Half-Heusler MgCuSn nanoparticles, were subjected to X-ray diffraction (XRD) analysis. Results of these analysis presented in FIG. 1, show that the first and second powders exhibit only peaks that match quite well with the Mg₂Si_{0.4}Sn_{0.6} phase referenced as a JCPDS file n^{o} 01-089-4254 (JCPDS for Joint Committee of Powder Diffraction Standards). A space group of Fm3m i.e. antifluorite structure, a lattice parameter of 6.580 Å, and a density of 3.056 g/cm³ characterize this phase of material (Mg₂Si_{0.4}Sn_{0.6}).

XRD results also show that each individual peak has a symmetrical profile. Consequently, for the first and the second powders the alloy of interest is completely formed after the mechanical alloying step. Therefore, the process of mechanical alloying is advantageously a reproducible process with the same XRD spectras and also with a constant yield.

According to an embodiment, the obtained first and second powders are densified by pressure-assisted sintering. Therefore, dense samples respectively of a first thermoelectric material and a second thermoelectric material were obtained. Advantageously, the obtained alloyed powder (first or second powder) is kept before the sintering step, in an inert atmosphere, for example in an argon atmosphere.

To create fully dense specimens the sintering process was preferably performed by Spark Plasma Sintering (SPS). The SPS technique is advantageous because it allows sintering of materials in a few minutes with a high final relative density. This technique is based on the use of a pulsed current to enable fast heating (up to 600° C./min), and lower sintering temperatures. Thus, this technique allows a control of the grain size after sintering and the maintenance of nanometer-sized second phases dispersed into the sintered microstructure.

The SPS steps were performed under argon at 1035 hPa, using the equipment HPD-25 (FCT Systeme GmbH). Into the SPS machine, 2 grams of the first alloyed powder (Mg₂Si_{0.3875}Sn_{0.6}Sb_{0.0125}) and of the second alloyed powder (Mg₂Si_{0.3875}Sn_{0.6}Sb_{0.0125}:MgCuSn Half-Heusler nanoparticles) were introduced separately into a 20 mm diameter graphite die without any previous pre-shaping.

For sintering, the SPS machine was closed by graphite punches at both sides, which transmit the uniaxial pressure. DC pulses are delivered to the die by the punches allowing the temperature to rise quickly with a heating rate of about 100° C./min.

The temperature is controlled via a thermocouple located into the wall of the graphite die, enabling the adjustment of the power output. Several tests of sintering were performed at different temperatures, and fully dense samples with a diameter of 20 mm were obtained. The maximum density is reached in the range 590-630° C. under a load of about 50 MPa for both first and second sintered powders.

The SPS machine advantageously allows to obtain data showing the densification rate curve which is based on the displacement of the pistons i.e. graphite punches that press the powder to be sintered. Samples provided from the first or the second alloyed powder with a relative density of 98.1% on temperature as low as 590 or 630° C. were manufactured, respectively.

According to a particular embodiment, the spark plasma sintering step comprises a pressure step performed at a sintering temperature Tₛ arranged between 500 and 720° C. inclusive, during a soak time arranged preferably between 1 and 15 minutes. Preferably, the pressure is arranged between 5 and 100 MPa, and more preferably between 35 and 50 MPa.

More preferably, the pressure step comprises consecutively:
a first sintering step during a non-zero first soak time t_{S1} less than 15 minutes inclusive, the first sintering step being performed under a first pressure Pₛ₁ arranged between 5 and 100 MPa inclusive,
a pressure decrease step during a decrease time t_{R} arranged between 1 and 30 minutes.

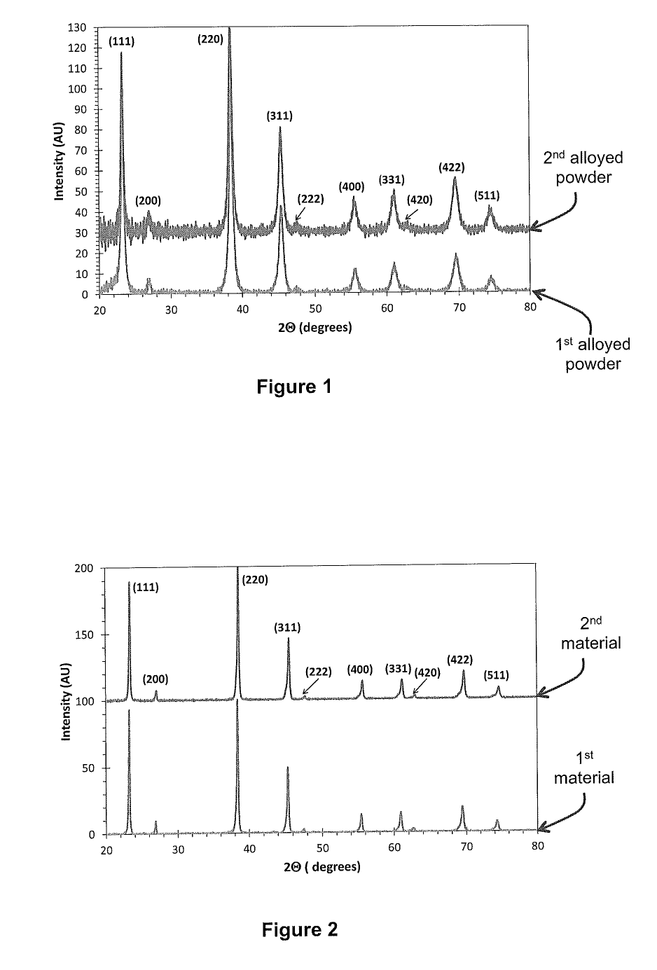

After sintering, the first obtained thermoelectric material and the second obtained thermoelectric material, i.e. respectively without and with the Half-Heusler MgCuSn nanoparticles, were subjected to XRD analysis presented in FIG. 2.

Results of these analysis show that the first and second materials exhibit only peaks that match with the Mg₂Si_{0.4}Sn_{0.6} phase having a lattice parameter of 6.6183 Å.

Smaller grains during sintering can be achieved by higher heating rate and higher cooling rate. Densification curve given by the SPS machine shows a 500° C.-720° C. sintering temperature range where the best thermoelectric properties are achieved. However, this temperature range is narrow, and important heating rate could lead to the sample's melting. For easily manufacturing a thermoelectric device, solid state sintering is preferred. Thus, the spark plasma sintering step is preferably performed at a sintering temperature T_{S} arranged between 570 and 650° C. inclusive.

According to a particular embodiment, the sintering process is performed in a SPS machine wherein the sintering process comprises a specific cooling step performed and controlled by the SPS machine, after the pressure step. The cooling step is performed so as to decrease the temperature within the spark plasma sintering machine from the sintering temperature Tₛ to a cooling temperature Tₒ.

Preferably, the cooling step is performed with a cooling rate arranged between 10° C./min and 600° C./min until reaching the cooling temperature T_{c} arranged between 150 and 400° C. Advantageously, the cooling step contribute to avoid breaking of samples during the SPS process.

For each as-sintered thermoelectric material (with and without Half-Heusler nanoparticles), fully dense samples were cut to create rods with dimension of 15×3×1.8 mm, parallelepipeds with dimension of 10×10×1.8 mm, and disks having a 5.2 mm diameter and a thickness of 1 mm.

Samples having rod form were analyzed in order to measure the Seebeck coefficient and the electrical conductivity by using the ZEM-3 equipment distributed by ULVAC Company. A cycle of 50 to 500° C. was programmed with temperature gradient ΔT of 10, 20 and 50° C. (ΔT represents the temperature difference between the electrodes).

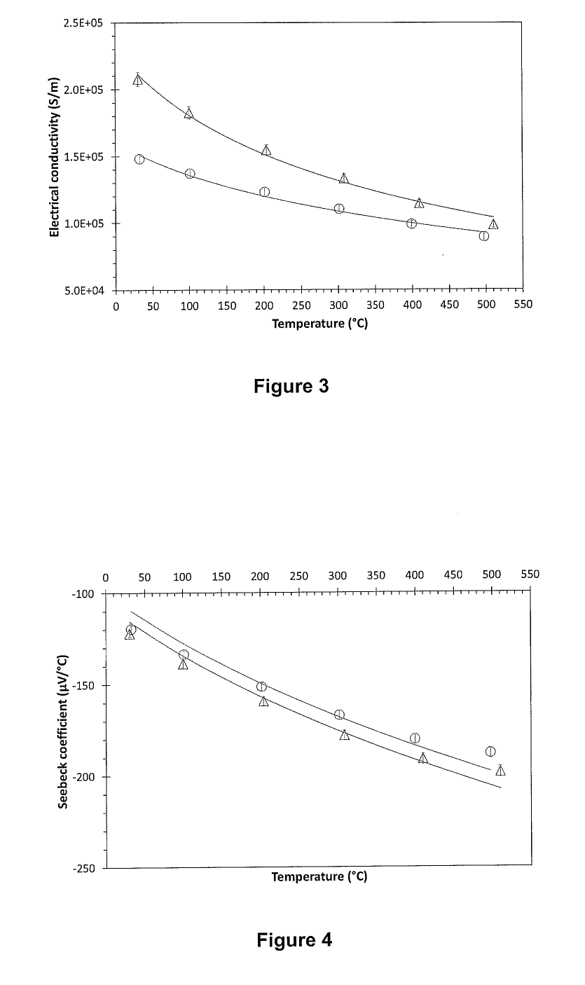

FIG. 3 illustrates two plots representing the temperature variations of the measured electrical conductivity for the first thermoelectric material and the second thermoelectric material. The plot with circle symbols corresponds to the first material (Mg₂Si_{0.3875}Sn_{0.6}Sb_{0.0125} without Half-Heusler inclusions), and the plot with triangle symbols corresponds to the second material (Mg₂Si_{0.3875}Sn_{0.6}Sb_{0.0125} with 1.7 vol % of MgCuSn Half-Heusler nanoparticles).

By comparing the first “standard” material with the second improved material, we can observe a difference in electrical conductivity. The improved adjunction of the Half-Heusler MgCuSn nanoparticles leads to an increase of the electrical conductivity. Whatever the temperature of interest, the second improved thermoelectric material exhibits the highest electrical conductivity. Particularly, at room temperature the electrical conductivity for the second thermoelectric material is 25% much higher than that for the first standard material. The nature of Half-Heusler materials, especially the MgCuSn nanoparticles leads advantageously to a higher grain size in the second thermoelectric material and therefore to an increase of the electrical conductivity.

FIG. 4 illustrates two plots representing the temperature variations of the measured Seebeck coefficient for the first thermoelectric material and the second thermoelectric material. The plot with circle symbols corresponds to the first material, and the plot with triangle symbols corresponds to the second material. By comparing the first “standard” material with the second material, we can observe that both first and second thermoelectric materials exhibit the desired N-type conduction, with very close Seebeck coefficient values for a given temperature.

Samples having parallelepiped and disk shapes were analyzed in order to measure the thermal conductivity by using the LFA457 MicroFlash® equipment distributed by NETZSCH Company. Cube samples allow to obtain the thermal diffusivity using Cowan distribution, and disk samples were used to measure heat capacity. Thus, the thermal conductivity of the thermoelectric materials was deduced from the following formula:

κ=ρcₚD

where ρ is the density of the sample, cₚ is the heat capacity and D is diffusivity of the thermoelectric material.

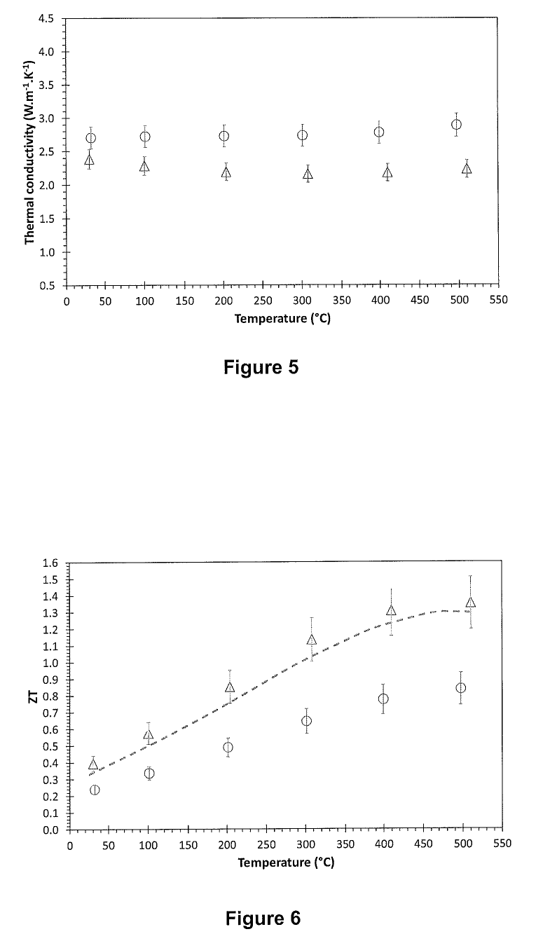

FIG. 5 illustrates two plots representing the temperature variations of the measured thermal conductivity for the first thermoelectric material and the second thermoelectric material. The plot with circle symbols corresponds to the first material, and the plot with triangle symbols corresponds to the second material. By comparing the first “standard” material with the second improved material, we can observe that whatever the temperature of interest, the thermal conductivity is lower for the second improved thermoelectric material.

Indeed, the compatibility of Half-Heusler MgCuSn inclusions with the antifluorite matrix leads to a high concentration of nanometer-sized inclusions/nodules, which are homogeneously dispersed in the matrix. Moreover, the adjunction of a small volume percent (1.7 vol %) of MgCuSn nanoparticles in the matrix allows, in all likelihood, an efficient perturbation of lattice vibrations, lowering thus strongly the lattice thermal conductivity.

The figure of merit, ZT can then be deduced from the measured values of the Seebeck coefficient, the electrical conductivity and the thermal conductivity. FIG. 6 illustrates two plots representing the temperature variations of the measured ZT value for the first thermoelectric material and the second thermoelectric material. The plot with circle symbols corresponds to the first material, and the plot with triangle symbols corresponds to the second material. FIG. 6 illustrates also a third plot (dashed line) representing the temperature variations of a measured ZT value for Mg₂Si₁₋ₓSnₓ thermoelectric material studied by Liu et al. in the article published in Physical Review Letters (108, 166601).

By comparing the first “standard” material and Liu et al. material with the second improved material, we can observe that a ZT peak value around 1.3-1.4 is obtained at 510° C. for the second improved thermoelectric material of Mg₂Si_{0.3875}Sn_{0.6}Sb_{0.0125}:MgCuSn Half-Heusler nanoparticles. Moreover, whatever the temperature of interest, the ZT value is higher for the second improved thermoelectric material. It is 60% higher than the ZT value obtained for the first thermoelectric material without the Half-Heusler inclusions at a temperature of 510° C.

The material based on Mg₂Si_{0.3875}Sn_{0.6}Sb_{0.0125}:MgCuSn Half-Heusler nanoparticles, according to the present invention is an efficient thermoelectric material, which is easy to manufacture. Indeed, a main advantage of this improved thermoelectric material is that it has been manufactured using only two steps: mechanical alloying followed by spark plasma sintering. Unlike similar thermoelectric materials of the literature, for example Liu et al. material, that are much more complex to manufacture. Particularly such materials manufacturing process uses many steps. Furthermore, the thermoelectric material is in a solid state, and is based on abundant and non-toxic material. Therefore, this type of improved thermoelectric material can advantageously allow the manufacturing of an efficient TE conversion device.

1. A thermoelectric compound comprising :
a first thermoelectric material having an antifluorite matrix,
a second material of the Half-Heusler structure phase forming embedded inclusions in the antifluorite matrix made of the first thermoelectric material.

2. The thermoelectric compound according to claim 1 wherein the antifluorite matrix having a composition expressed by a formula:
Mg₂SiₓSn₁₋ₓ
where, x is a value satisfying 0.35<x<0.4,
and wherein the embedded inclusions are MgCuSn nanoparticles.

3. The thermoelectric compound according to claim 1 wherein the antifluorite matrix having a composition expressed by a formula:
Mg₂SiₓA_{y}Sn_{1-x-y}
where, A is Sb or Bi, x is a value satisfying 0.35<x<0.4, and y is a value satisfying 0.005<y<0.03,
and wherein the embedded inclusions are MgCuSn nanoparticles.

4. The thermoelectric compound according to claim 3 wherein the thermoelectric material has a dimensionless figure of merit ZT higher than 1.2-1.3 at 510° C.

5. The thermoelectric compound according to claim 3, comprising a volume percent V_{HH} of MgCuSn nanoparticles satisfying:
1.4 vol %<=V_{HH}2132 2.0 vol %

6. A thermoelectric conversion module, comprising:
a first element made from a first N-type thermoelectric material,
a second element made from a second P-type thermoelectric material,
an electric connecting element in electric contact with the first element and the second element so as to form a thermocouple,
wherein at least the first N-type thermoelectric material is based of the thermoelectric compound according to claim 1.

7. A method of manufacturing a thermoelectric compound comprising:
providing a half-Heusler compound of MgCuSn nanoparticles,
obtaining a powder by mechanical alloying, Mg chips, Si powder, Sn powder and Sb powder, with the half-Heusler compound of MgCuSn nanoparticles and with a process control agent solution,
wherein the weight percent V_{c} of the process control agent solution is comprised between 0.5 wt % and 4.0 wt % and wherein the volume percent V_{HH} of the Half-Heusler compound of MgCuSn nanoparticles is comprised between 1.4 vol % and 2.0 vol % inclusive.

8. The method according to the claim 7, wherein the mechanical alloying is performed in a high planetary mill comprising a sealed zirconia jar provided with at least two zirconia balls, and wherein the ratio of the mass of the balls to the mass of the powder is kept between 15 and 30.

9. The method according to the claim 7, wherein the process control agent solution is a cyclohexane solution.

10. The method according to the claim 8, wherein the Mg chips, the Si powder, the Sn powder, the Sb powder, the Half-Heusler compound of MgCuSn nanoparticles and the process control agent solution are placed into the zirconia jar inside a glove box in an inert atmosphere.

11. The method according to the claim 8, wherein the sealed zirconia jar is milled for a total time arranged between 10 and 100 hours at a speed arranged between 200 and 400 rpm.

12. The method according to the claim 10, wherein milling is performed with a rotation sequence of 10 minutes in a first direction, followed by a pause of 2 minutes and an other rotation sequence in a second direction opposite to the first direction.

13. The method according to the claim 7 wherein the obtained powder is sintered so as to obtain a dense sample of the thermoelectric material.

14. The method according to the claim 13 wherein the obtained powder is kept in an inert atmosphere before the sintering step.

15. The method according to claim 13 wherein the sintering process is performed by spark plasma sintering and comprises at least one pressure step performed at a pressure arranged between 5 and 100 MPa, and at a sintering temperature TS arranged between 500 and 720° C. inclusive.

16. The method according to claim 14 wherein the sintering process is performed in a spark plasma sintering machine and wherein the sintering process comprises a specific cooling step performed and controlled by the spark plasma sintering machine after the pressure step so as to decrease the temperature of the sintered material within the spark plasma sintering machine from the sintering temperature Ts to a cooling temperature Tc arranged between 150 and 400° C.

17. The method according to claim 15 wherein the cooling step is performed with a cooling rate arranged between 10° C./min and 600° C/min until reaching the cooling temperature Tc.
